(19) United States
(12) Patent Application Publication
(10) Pub. No.: US 2011/0240111 A1
(43) Pub. Date: Oct. 6, 2011

(54) CARBON NANOTUBE ASSEMBLY, SOLAR CELL, WAVEGUIDE AND SUBSTRATE WITH THE SAME CARBON NANOTUBE ASSEMBLY

(76) Inventors: Yuichi Yamazaki, Inagi-shi (JP); Tadashi Sakai, Yokohama-shi (JP); Koji Asakawa, Kawasaki-shi (JP)

(21) Appl. No.: 12/879,785

(22) Filed: Sep. 10, 2010

(30) Foreign Application Priority Data
Mar. 30, 2010 (JP) 2010-079817

(51) Int. Cl. H01L 31/0216; G02B 6/42; B32B 5/16; H01L 31/04; B32B 3/30; B82Y 20/00

(52) U.S. Cl. 136/256; 250/227.11; 428/338; 428/323; 428/172; 977/742; 977/954; 977/950

(57) ABSTRACT

According to one embodiment, a carbon nanotube assembly includes a plurality of carbon nanotubes having a length of 10 μm or less in a major axis direction assembled with a space filling rate of 30% or more.

### CROSS-REFERENCE TO RELATED APPLICATIONS

This application is based upon and claims the benefit of priority from Japanese Patent Application No. 2010-079817, filed Mar. 30, 2010; the entire contents of which are incorporated herein by reference.

### FIELD

Embodiments described herein relate generally to a carbon nanotube assembly, a solar cell, a waveguide and a substrate with the same carbon nanotube assembly.

### BACKGROUND

Various types of fine materials having structure of a nanometer order have been developed very actively by the progress of techniques such as material synthesis and fine machining in recent years. In particular, quantum dot, quantum wire and the like are approximately 1 to 10 nm in size, and it has been widely known that unique properties are developed in this size by quantum effect. For example, with regard to the quantum dot, a change in diameter by several nanometers allows the band gap to be greatly changed and allows the quantum dot exhibiting diverse luminescent colors to be produced. In the case of rendering gold and silver finer, plasmon may be easily excited by absorbing light with wavelengths in the visible range. The plasmon is a phenomenon mainly observed in metal, such that free electrons in a material vibrate collectively by absorbing light with a specific wavelength. Various types of applications of unique optical properties of such fine materials have been proposed.

The fine materials need to be produced in high density for improving these effects. Examples of a producing method thereof include self-assembly, fine machining and the utilization of a template. However, the self-assembly offers higher density with difficulty due to aggregation and fusion phenomenon of the fine materials; the case of the fine machining and the utilization of a template may not offer higher density due to a limit to accuracy of machining though excellent in position control. The above-mentioned effects are developed by the confinement of electrons to a region of a nanometer order, so that the contact of the fine materials with each other does not offer the development of the above-mentioned effects. Thus, a technique for filling an insulating material between the fine materials is provided but has a limit in offering higher density.

As described above, it is very difficult to produce an assembly such that the fine materials having a size of a nanometer order are densified while maintaining the quantum effect.

A carbon nanotube (CNT) such that a carbon sheet (graphene) is tubed is a typical nanomaterial having a diameter of a nanometer order, and physical properties thereof are unique in a parallel direction to the CNT axis (major axis). Even though the CNTs contact each other, only as weak an interaction as that between graphite layers functions, so that the effect characteristic of the fine materials is not lost.

It is not easy to assemble the CNT with a space filling rate of 30% or more; for example, a method has been known such that liquid is dropped on the CNTs, which are aggregated by surface tension functioning during the evaporation of the liquid to increase the space filling rate (see D. N. Futaba et al., Nature Materials 5 [2006] 987-994). However, in this method, high space filling rate is obtained by aggregating the other end of the CNT with low space filling rate, whose one end is retained on a substrate, so that the space filling rate may not be increased unless the CNT is sufficiently long in the major axis direction. We have confirmed that light absorbance has no wavelength dependence even though the CNT assembly longer than 10 μm is irradiated with light.

### BRIEF DESCRIPTION OF THE DRAWINGS

FIG. 1A is a perspective view showing a substrate with a CNT assembly according to Example 1;

FIG. 1B is an SEM image of the CNT assembly 11 of FIG. 1A;

FIG. 1C is a view showing an incident light spectrum and a reflected light spectrum for the CNT assembly of Example 1;

FIG. 1D is a view showing an incident light spectrum and a reflected light spectrum for the CNT assembly of Comparative Example;

FIG. 2 is a perspective view showing a CNT assembly provided with a different material inside a CNT of Example 2;

FIG. 3A is a cross-sectional view showing a solar cell of Example 3;

FIG. 3B is a cross-sectional view showing a solar cell of Modification Example 1;

FIG. 3C is a cross-sectional view showing a solar cell of Modification Example 2;

FIG. 4A is a perspective view showing an optical waveguide of Example 4;

FIG. 4B is a cross-sectional view showing an optical waveguide of Modification Example 3; and

FIG. 5 is a perspective view showing an optical property evaluation system of Example 5.

### DETAILED DESCRIPTION

In general, according to one embodiment, a carbon nanotube assembly includes a plurality of carbon nanotubes having a length of 10 μm or less in a major axis direction assembled with a space filling rate of 30% or more.

Examples are hereinafter described on the basis of the drawings.

### Example 1

The CNT assembly (carbon nanotube forest) according to the embodiment comprises a plurality of CNTs having a length of 10 μm or less in the major axis direction assembled with a space filling rate of 30% or more.

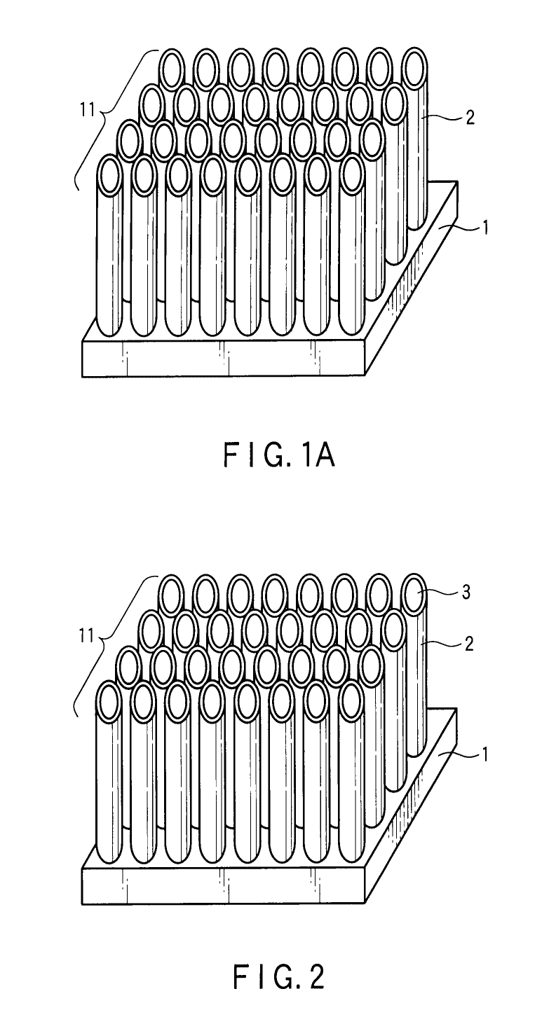

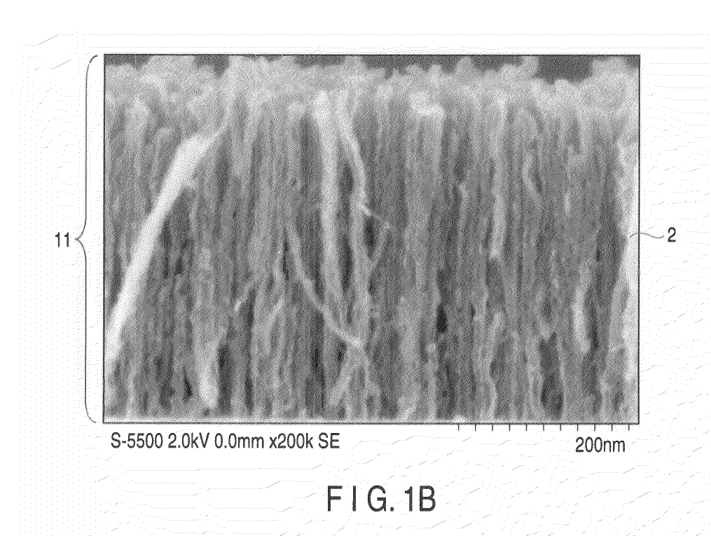

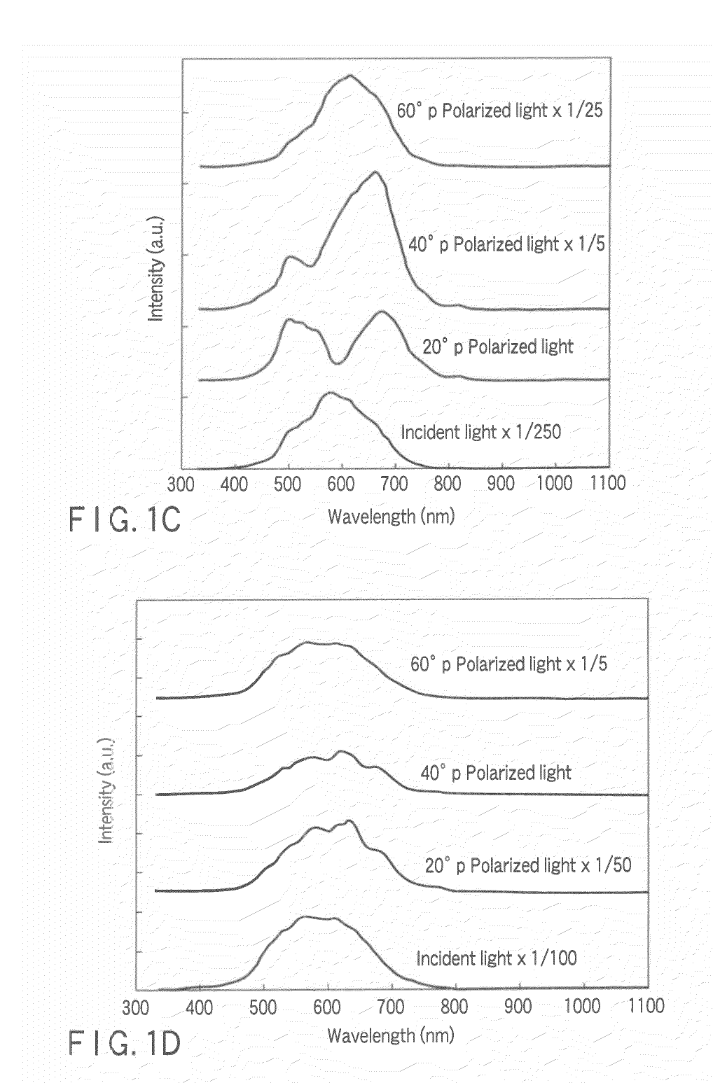

FIG. 1A is one typical example of the embodiment and a perspective view showing a substrate with a CNT assembly 11 obtained by directly growing a plurality of CNTs 2 on a substrate 1. The CNT assembly such that the CNTs 2 assemble with a space filling rate of 30% or more is provided on one principal surface of the substrate 1. The length of this CNT assembly in the major axis direction (direction perpendicular to the substrate in FIG. 1) is 10 μm or less.

The space filling rate is a percentage of the total sum of each CNT 2 cross-sectional area to an area occupied by the CNT assembly 11 in a cross section perpendicular to the length direction of the CNT 2. The CNT 2 is approximately cylindrical so that this area ratio may be regarded as the space filling rate. The hollow portion inside each CNT 2 is determined to belong to the CNT 2 area. The area occupied by the CNT assembly 11 is an area of a region prescribed by the CNT 2 group forming the outer edge of the CNT assembly 11 in a cross section perpendicular to the major axis direction of the CNT 2. When the occupied area of the CNT assembly 11, the total number of the CNTs 2, and the average diameter of the CNT 2 are regarded as S [cm²], D [pieces], and R [cm], respectively, the space filling rate is represented by the following expression.

Space filling rate[%]=D×π(R/2)²×100/S

The occupied area of the CNT assembly 11, the total number of the CNTs 2, and the average diameter of the CNT 2 may be measured from a scanning electron microscope (SEM) and transmission electron microscope (TEM) image.

The CNT may adopt a monolayer structure formed out of a single-layer tubed carbon sheet and a multilayer structure formed out of a plural-layer tubed carbon sheet; the present Example may be implemented for the CNT in both shapes.

The material for the substrate 1 does not particularly matter; yet, the material containing at least one of Ta, Ti, Ta nitride and Ti nitride is preferably used for promoting the growth of the CNT 2. Alternatively, a product obtained by properly combining and depositing two types or more of materials selected from the group may be used for the substrate 1. In the case of producing a device by using the CNT assembly 11, the material suitable for the device may be used.

FIG. 1B is an SEM image showing a cross section of the CNT assembly 11 of FIG. 1A in the direction perpendicular to the substrate 1. The CNT 2 was approximately parallel to each other and approximately perpendicular to the substrate 1. The length of each CNT 2 in the major axis direction was 400 nm on average. The diameter of the CNT 2 was 5 to 6 nm on average. The CNT 2 shown in FIG. 1B was of a six-layer structure on average through the analysis by TEM. The space filling rate of the CNT assembly 11 was approximately 50 to 60% according to the above formula.

We have found out that such a CNT assembly 11 having a length of 10 μm or less in the major axis direction has a large light absorption peak, which is different from a light absorption peak resulting from interband transition of the CNT 2 itself, in a wavelength range of 300 to 2000 nm. That is to say, when such a CNT assembly 11 is irradiated with light, the reflected light spectrum has a greatly different shape from the irradiation light spectrum. The reason for this large difference is that the CNT assembly 11 exhibits light absorption derived from the interband transition as well as a cause different therefrom. This light absorption is described below.

When a material is irradiated with light, part of the irradiated light is absorbed in the material and unabsorbed light is transmitted or reflected. In comparing the irradiation light spectrum with the reflected light spectrum, the difference corresponds to the absorbed light. Part of the absorbed light is used as excitation energy of atoms and molecules composing the material to contribute to the interband transition of electrons.

FIG. 1C is a view showing an incident light spectrum and reflected light spectra in a wavelength range of 300 to 1100 nm when the CNT assembly of FIG. 1B is irradiated with the incident light. The reflected light obtained from each incident light was measured while varying the incident angle of the incident light into 20, 40 and 60 degrees. That is to say, the obtained reflected light is of three types of reflection angles of 20, 40 and 60 degrees. The p polarized light such that an electric field component of the light was parallel to the incidence plane (principal surface of the substrate 1) was used as the incident light.

The incident light spectrum, the reflected light spectrum at a reflection angle of 40 degrees, and the reflected light spectrum at a reflection angle of 60 degrees are shown at intensity of one two hundred-fiftieth, one fifth, and one twenty-fifth, respectively. The incident light spectrum is p polarized light, so that the obtained reflected light spectrum is also p polarized light. In order to easily understand the shape of each spectrum, the position of each spectrum at intensity (vertical axis) of 0 is shifted in a longitudinal direction, and the intensity at a wavelength of 900 to 1100 nm was 0 in any spectrum.

The difference between the incident light spectrum and the reflected light spectrum signifies the spectrum absorbed in the CNT assembly 11. In comparing the reflected light spectrum at a reflection angle of 60 degrees with the incident light spectrum, the intensity differs but the shape is similar. Thus, it is found that the reflected light at a reflection angle of 60 degrees was absorbed in the CNT assembly 11 at approximately the same ratio in any wavelength. On the other hand, in comparing the shape of the reflected light spectrum at a reflection angle of 20 degrees and the incident light spectrum, the intensity in the vicinity of a wavelength of 600 nm was high in the incident light spectrum, while the intensity in the vicinity of a wavelength of 600 nm was low in the reflected light spectrum. Thus, it is found that the reflected light at a reflection angle of 20 degrees is easily absorbed in the CNT assembly 11 in the vicinity of a wavelength of 600 nm.

Each reflected light spectrum has peaks in the vicinity of 500 and 670 nm, and these two peaks differed in a relation of intensity. That is to say, the intensity of both peaks is approximately the same in the reflected light spectrum at a reflection angle of 20 degrees, while the peak in the vicinity of a wavelength of 670 nm was larger than the peak in the vicinity of a wavelength of 500 nm in the reflected light spectrum at a reflection angle of 40 and 60 degrees.

With regard to the peak in the vicinity of 500 nm, the larger reflection angle brought the smaller intensity; on the contrary, with regard to the peak in the vicinity of 650 nm, the larger reflection angle brought the larger intensity.

Thus, the optical properties characteristic of the CNT assembly 11 are to have a plurality of peaks, which exhibit a tendency for the reflected light intensity to increase or decrease as the reflection angle becomes larger, in a wavelength range of 300 to 2000 nm.

One of the main uses for light energy absorbed in the CNT is interband transition. In the case where most of the absorbed light energy is used for the interband transition, it has been known that the reflected light spectrum has a peak which becomes smaller in intensity as the reflection angle becomes larger. Thus, it is found that the light energy absorbed in the CNT 2 is also used except for the interband transition.

It is presumed that plasmon is involved in the absorption of this light energy except for the interband transition. That is to say, it is conceived that the CNT assembly 11 of FIG. 1B absorbs the light energy to cause the interband transition as well as plasmon excitation. A possibility of causing the plasmon by irradiating a slender material with light is limited to a case where the major axis of the material is a length capable of raising a standing wave. That is to say, if the length of the material in the major axis direction is several times or less the wavelength of the irradiation light, the standing wave may be raised to cause the plasmon. However, a higher-order plasmon mode tends to be caused with a greater difficulty, so that too long CNT assembly 11 excites the plasmon with difficulty by light in a visible to infrared range.

A device comprising a solar cell and an optical waveguide, which operates by absorbing light, receives light of mainly 300 to 2000 nm as the incident light, so that the plasmon is caused by the incident light in this wavelength range if the length of the CNT assembly 11 is 10 μm or less. In particular, in the case where the incident light is visible light, the light absorption probability (probability of causing the plasmon) is high when the length in the major axis direction is around 100 to 500 nm. Accordingly, with regard to the CNT assembly of FIG. 1B, it is conceived that the standing wave was raised to cause the plasmon for the reason that 400 nm was equal to the wavelength of the incident light. Thus, the CNT assembly 11 may absorb part of the incident light to cause the plasmon if the length thereof is 10 μm or less.

It was confirmed that the CNT assembly 11 exhibits color while depending on the reflection angle.

FIG. 1D is Comparative Example relative to FIG. 1C, and a view showing an incident light spectrum and reflected light spectra in a wavelength range of 300 to 1100 nm when the CNT assembly having a space filling rate of approximately 10% and a length of approximately 2 μm is irradiated with light. The p polarized light is used as the incident light and the reflected light spectra show p polarized light at reflection angles of 20, 40 and 60 degrees. The CNT forming the CNT assembly of FIG. 1D was of an eight-layer structure on average. The volume of the CNT assembly of FIG. 1D (excluding the hollow portion of the CNT) was smaller by approximately 10% than that of the CNT assembly 11 of FIG. 1C.

The reflected light spectra scarcely differed in shape from the incident light spectrum. Also, a peak whose intensity increases depending on the reflection angle was not observed. Though the reflected light spectrum at a reflection angle of 20 degrees has a small light absorption peak, the intensity thereof was small as compared with the CNT 2 of FIG. 1C. It is conceived that the cause thereof is that the space filling rate of the CNT assembly 11 was low and the length thereof was long.

It was confirmed that the CNT used for FIG. 1D exhibited a color similar to black in appearance even though observed from any angle.

As described above, it is conceived that the CNT assembly having a length of 10 μm or less in the major axis direction is irradiated with light with a wavelength of 300 to 2000 nm to thereby cause the plasmon.

A higher space filling rate of the CNT assembly 11 brings a shorter distance between the CNTs 2, so that the plasmon caused in each CNT 2 may interact to reinforce the electric field.

The light absorption by the plasmon causes near-field light around the space of the CNT 2. Generally, the electric field intensity of the near-field light decreases exponentially with respect to the distance from a material surface, and extends merely by approximately 10 to 100 nm. When the space filling rate of the CNT assembly 11 is high, the distance between the CNTs becomes so short as 10 nm or less that the interaction between the CNTs 2, which is developed through the electric field extending around each CNT 2, may be improved.

The reflected light spectra at a reflection angle of 20 degrees of FIGS. 1C and 1D are compared with each other. The peak intensity of the reflected light spectrum at a reflection angle of 20 degrees of FIG. 1C is approximately 1/250 of the incident light spectrum of FIG. 1C, and approximately 249/250 of the incident light was absorbed in the CNT assembly in the peak wavelength. On the other hand, the peak intensity of the reflected light spectrum at a reflection angle of 20 degrees of FIG. 1D is 1/2 of the incident light spectrum of FIG. 1D, and 1/2 of the incident light was absorbed in the CNT assembly in the peak wavelength. That is to say, the CNT assembly 11 used in FIG. 1C offered approximately twice the light absorbed amount of the CNT assembly 11 used in FIG. 1D.

The light energy used for the interband transition increases monotonically in accordance with volume (atomicity) increase of the material absorbing the light. As described above, though the CNT assembly 11 used in FIG. 1C is larger in volume by only approximately 10% than the CNT assembly 11 used in FIG. 1D, the light absorbed amount is larger by approximately twice. It is found from this large light absorbed amount that the CNT assembly 11 used in FIG. 1C has high plasmon excitation efficiency.

Thus, the CNT assembly having a length of 10 μm or less in the major axis direction and high space filling rate is applied to the device which operates by absorbing light, so that the operating efficiency is expected to improve by the function of the effect of reinforcing the electric field and the effect of improving the intensity of the near-field light.

If the space filling rate of the CNT assembly 11 is 30% or more, the interaction effect of the plasmon caused in each CNT 2 may be expected to obtain the effect as described above. Specific examples such that the CNT assembly 11 having a length of 10 μm or less in the major axis direction and a space filling rate of 30% or more is used for the device are shown in Examples 3 to 5.

Ordinarily, it is very difficult to make substances approach each other in a nanometer order without contacting. In the case where substances contact and fuse with each other to change in shape, the plasmon is caused with difficulty and the excitation conditions of the plasmon are changed. However, the CNT 2 is so incapable of approaching up to the interlayer distance or less of graphite in an ordinary state as to bring no possibilities of contacting. It has been known that the CNT 2 has metallic properties ordinarily at a probability of 1/3 and becomes metallic at a percentage of approximately 100% if the diameter thereof is approximately 3 nm or more; free electrons necessary for causing the plasmon are present in the CNT 2. Accordingly, it is conceived that the CNT is the most appropriate substance for obtaining the effect as described above.

One example of a method of growing the CNT 2 on the substrate 1 is as follows. That is to say, the growth of the CNT 2 is performed by a multistage growth method such that a plasma CVD device is used by using a catalyst material having Co, Ni, Fe and the like. First, a thin film (catalyst) having Co, Ni, Fe and the like is formed on the substrate, and the thin film is atomized while irradiating gas made into plasma on this thin film. This gas is determined at gas containing no carbon; for example, hydrogen gas and rare gas are used. The particulates are restrained from aggregating by irradiating the gas made into plasma for a certain time also after being atomized. Next, gas containing hydrocarbon is made into plasma in a temperature range lower than the growth temperature, and irradiated on the thin film for a short time to form a graphite layer in the catalyst particulates. Subsequently, the graphite layer is regarded as a seed crystal, which is irradiated with the gas containing hydrocarbon, made into plasma, to grow CNT.

As described above, the CNT assembly 11 needs to have a space filling rate of 30% or more and a length of 10 μm or less in the major axis direction for exhibiting great light absorption in a wavelength of 300 to 2000 nm.

### Example 2

The CNT assembly according to Example 2 has a structure such that a different material 3 is provided in the hollow portion of the CNT 2 composing the CNT assembly 11, as shown in a perspective view of FIG. 2.

It is expected that the wavelength for absorbing by the occurrence of the plasmon is somewhat shifted by providing the different material 3 inside the CNT 2, as compared with the case of not providing the different material 3. A material with a smaller diameter than the diameter of the CNT 2 is used as the different material 3. Examples thereof include fullerene, various types of metal particulates, and semiconductor particulates. It is expected that the wavelength for absorbing light is changed by the type and number of the different material 3 provided inside the CNT 2. The reason therefor is that the band structure of the CNT 2 is modulated by the interaction with the different material.

Accordingly, the modification of the type and number of the different material 3 allows the light absorption peak of the CNT assembly 11 to be adjusted.

The placement of the different material 3 inside the CNT 2 is performed in the following manner. That is to say, the CNT 2 is subject to heat treatment or acid solution treatment in the presence of oxygen, and the tip thereof (end on the side not fixed to the substrate 1) is opened to place the different material inside the CNT 2.

### Example 3

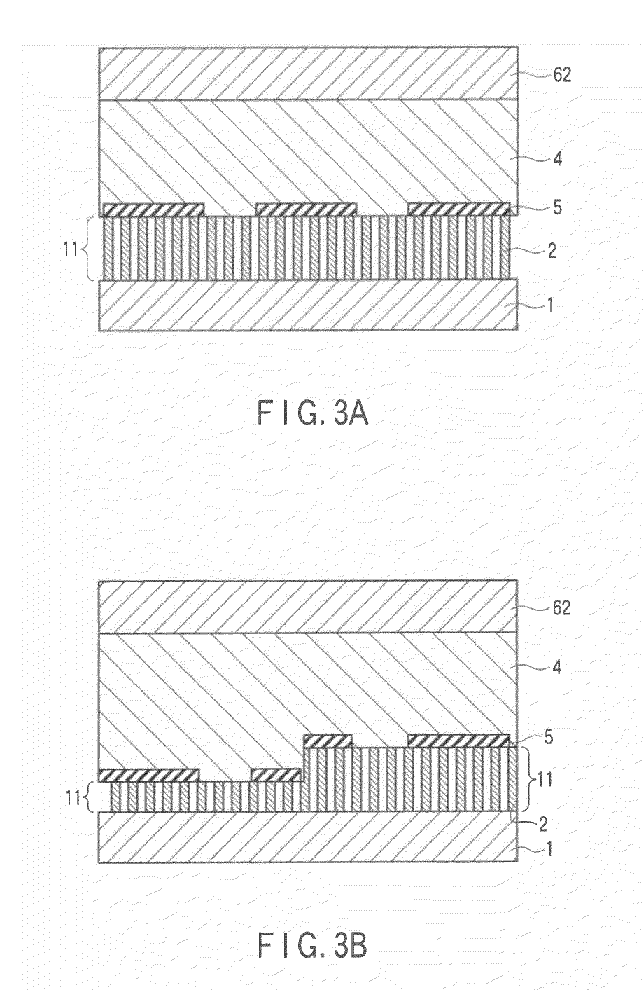

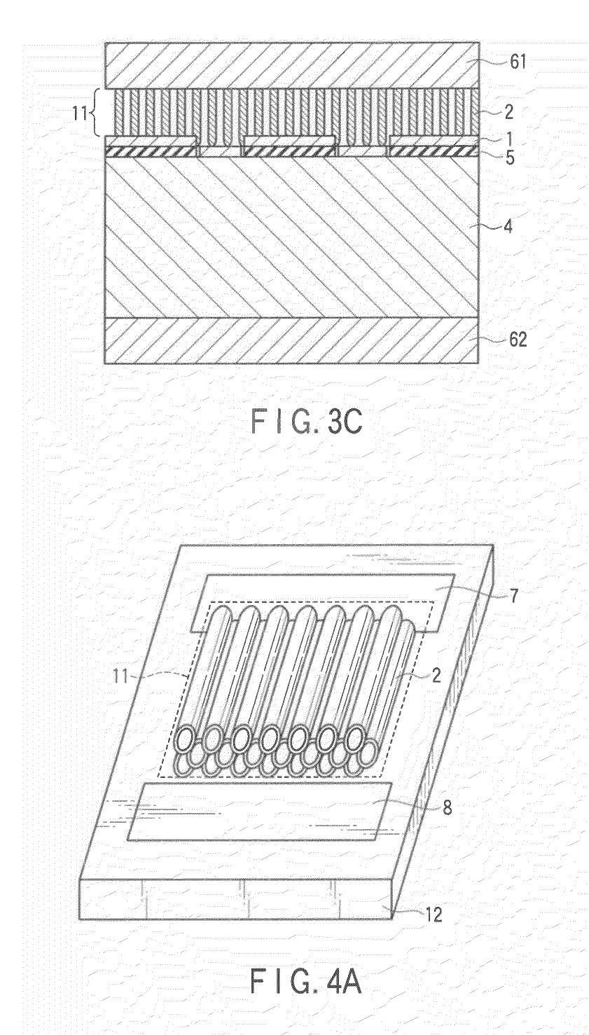

Example 3 is an application example of the CNT assembly 11 to a solar cell. FIG. 3A is a cross-sectional view showing a solar cell using the CNT assembly 11 of Example 1. This solar cell has a structure such that an electron-hole pair generating layer 4 is laminated on the CNT assembly 11 provided on the substrate 1.

In the solar cell shown in FIG. 3A, a plurality of spacers 5 are provided on the CNT assembly 11 at intervals, and the electron-hole pair generating layer 4 is provided over the spacers 5. An electrode 62 is provided on the electron-hole pair generating layer 4. In the Example, the substrate 1 provided with the CNT assembly 11 is electrically conductive and functions as an electrode.

Examples of the material for the electron-hole pair generating layer 4 include a semiconductor layer of pn junction and a semiconductor layer formed out of an organic thin film. A light transparent material with high electrical conductivity is used as the material for the electrode 62 and the substrate 1; examples thereof include indium-tin oxide (ITO). A dielectric material with lower refractive index than the CNT assembly 11 is used as the material for the spacers 5; examples thereof include SiO₂ and Al₂O₃.

Sunlight applied to the solar cell generally lies within a wavelength range of 300 to 1000 nm. When light is irradiated from the electrode 62 side, photoelectric conversion is caused in the electron-hole pair generating layer 4 and electric current flows between the substrate 1 (electrode) and the electrode 62. Part of the irradiated light is transmitted without being absorbed in the electron-hole pair generating layer 4. When this transmitted light is absorbed in the CNT assembly 11, the plasmon is excited, by which plasmon the electric field energy is locally reinforced. When this reinforced electric field extends to the electron-hole pair generating layer 4, an electron is excited in the electron-hole pair generating layer 4. Accordingly, the electron-hole pair generating efficiency of the solar cell may be improved by providing the CNT assembly 11.

In addition, the electric field by the plasmon generated in the CNT assembly 11 is further reinforced by providing the spacers 5. The reason therefor is that the electric field intensity has properties such as to become higher in the material with low refractive index than the material with high refractive index. The electric field reinforced in the CNT assembly 11 is further reinforced in the spacers 5. Accordingly, the electric field further reinforced by the spacers 5 extends to the electron-hole pair generating layer 4, so that the electron-hole pair generating efficiency may be further improved.

Depending on light transmission properties of the spacers 5, light occasionally reaches the CNT assembly 11 with difficulty by providing the spacers 5. On the other hand, as described above, the electric field intensity may be further reinforced by the spacers 5. In the case of a relation of such a trade-off, the light amount reaching from the gap between the spacers 5 to the CNT assembly and the effect of reinforcing the electric field by the spacers 5 are each optimized by properly adjusting the interval of the spacers 5.

The use of metal as the material for the substrate 1 allows the incident light not absorbed in the CNT assembly 11 to be reflected. This reflected light may be absorbed in the CNT assembly 11, so that the utilization efficiency of the light may be further improved.

Thus, a large photoelectric effect is caused in the electron-hole pair generating layer 4 by reinforcing the electric field in the CNT assembly 11 when light with a wavelength range of 300 to 1000 nm is applied, so that a solar cell with large electric power generating efficiency may be obtained. That is to say, a solar cell with large light utilization efficiency may be obtained.

This solar cell is produced in the following manner. First, the CNT assembly 11 is grown on the substrate 1, and the material for the spacers 5 is deposited in a film thereon and patterned to form the spacers 5. Next, a semiconductor layer is provided on the spacers 5 to form the electron-hole pair generating layer 4. Then, the electrode 62 is formed on the electron-hole pair generating layer 4. It is desirable that the temperature in growing the CNT 2 is approximately 500 to 800° C. in consideration of crystal quality of the CNT 2. The electron-hole pair generating layer 4 is provided after growing the CNT 2, so that there are no possibilities of the influence of the temperature for growing the CNT 2 on the electron-hole pair generating layer 4 even in the case of forming the electron-hole pair generating layer 4 out of a material with low heat resistance, such as the organic thin film.

### Modification Example 1

A solar cell of Modification Example 1 is provided with two types of the CNT assemblies 11 with different length. FIG. 3B is a cross-sectional view showing the solar cell of Modification Example 1. The other constitutions are the same as FIG. 3A, so that the description of the same portion is omitted by marking the same reference numerals.

As described above, the wavelength absorbed in the CNT assembly 11 to be capable of exciting the plasmon depends on the length of the CNT 2. Accordingly, two types of the CNT assemblies 11 have a light absorption peak corresponding to each length. For example, the CNT assembly 11 longer in length and the CNT assembly 11 shorter in length may be designed so as to mainly absorb red light and mainly absorb blue light, respectively. Thus, when two types of the CNT assemblies 11 with different length are formed, even though the light absorption intensity of one CNT assembly 11 is small in some wavelength range, the light absorption intensity of the other CNT assembly 11 is so large that the CNT assemblies 11 may compensate for light absorption intensity to each other. Accordingly, light in a wide wavelength range may be absorbed and the electric field energy may be reinforced, so that the amount for causing the photoelectric effect in the electron-hole pair generating layer 4 may be further increased. That is to say, a solar cell with greater light utilization efficiency and electrical output may be obtained.

The length of the CNT assembly 11 may be of three types or more. The length and area ratio of the CNT assembly 11 is designed such that the sum of the light absorption spectrum of plural types of the CNT assemblies 11 is the same as or similar to the transmitted light spectrum of the electron-hole pair generating layer 4; therefore, the light utilization efficiency of the solar cell may be further improved.

Examples of a method of forming two types of the CNT assemblies 11 include the following method. That is to say, the CNT assemblies 11 are formed into a uniform length on the substrate 1 to thereafter perform masking for part of the CNT assemblies 11. Then, the length of the CNT assemblies 11 of the portion with masking not performed is shortened by etching the portion with masking not performed through oxygen plasma. That is to say, etching is performed for a region in which the CNT assemblies 11 shorter in length are provided. The particulate diameter to be produced is somewhat changed by adjusting the catalyst thin film thickness. Generally, a larger particulate diameter brings a greater growth rate of the CNT which grows therefrom, so that the CNT assemblies 11 different in length may also be produced.

### Modification Example 2

FIG. 3C shows a structure such that the CNT assembly 11 is laminated on the electron-hole pair generating layer 4 (electrode 62 side irradiated with light). In a solar cell of Modification Example 2, a plurality of the spacers 5 are provided at intervals on the electron-hole pair generating layer 4 formed on the electrode 62. The substrate 1 is provided on the electron-hole pair generating layer 4 and the spacers 5. The CNT assembly 11 is provided on the substrate 1. Then, an electrode 61 is provided on the CNT assembly 11.

The description is omitted by marking the same reference numerals on the same portion as Example 2 and Modification Example 1.

A method of producing this solar cell is such that the spacers 5 are formed on the electron-hole pair generating layer 4 to form the substrate 1 thereon. The CNT assembly 11 is formed on the substrate 1 by the method of Example 1. Then, the electrode 61 is provided on the principal surface opposite to the principal surface of the electron-hole pair generating layer 4 provided with the spacers 5 to provide the electrode 62 on the CNT assembly 11.

In order to make the electric field reinforced in the CNT assembly 11 act sufficiently on the electron-hole pair generating layer 4, the thickness of the substrate 1 needs to be thinned as much as possible. The thickness of the substrate 1 is approximately 10 nm, for example.

### Example 4

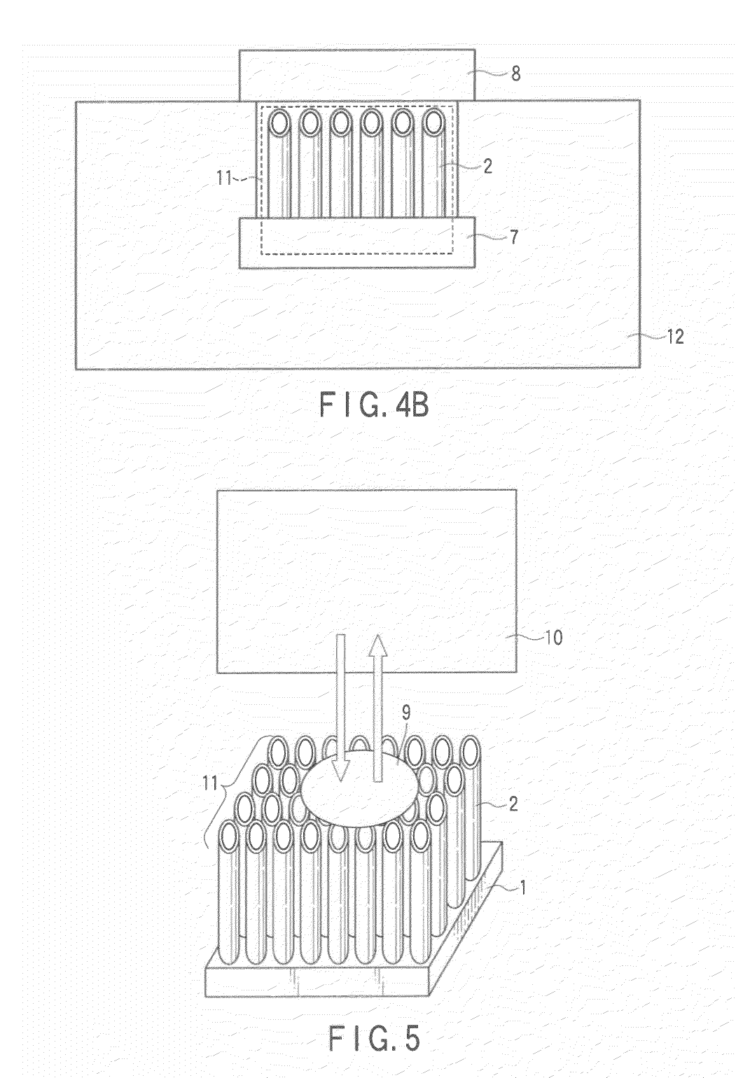

Example 4 is an application example of the CNT assembly 11 to an optical waveguide. FIG. 4A is a perspective view of an optical waveguide using the CNT assembly 11 of Example 1.

This optical waveguide is provided with the CNT 2 growing in a parallel direction to a flat plate 12. A light emitting element 7 is provided on one end of the CNT assembly 11 and a light receiving element 8 is provided on the other end thereof. The CNT assembly 11 is provided between the light emitting element 7 and the light receiving element 8.

In the Example, the CNT assembly 11 is obtained by growing the CNT while using the light emitting element 7 as a substrate. Thus, one end of the CNT assembly 11 contacts the light emitting element 7.

Devices for directly emitting the near-field light such as a near-field probe and a LED with a polarization controlling element may be used as the light emitting element 7.

For example, a near-field probe may be used as the light receiving element 8.

In such an optical waveguide, the light emitting element 7 irradiates light toward one end of the CNT assembly 11. One end of the CNT assembly 11 irradiated with light is excited to cause the plasmon. The near-field light is caused in proximity to the CNT 2 by this plasmon, and the light receiving element detects this near-field light on the other end of the CNT assembly 11.

Thus, a signal may be communicated by the optical waveguide using the CNT assembly 11 of Example 1.

The electric field intensity of the near-field light generated by the plasmon is so large that photodetectivity of the light receiving element 8 is improved by using the CNT assembly 11 as the waveguide. With regard to the optical waveguide such that a material except the CNT assembly 11 is used as the plasmon generation source, the plasmon is occasionally absorbed in the material itself and another material contacting the material to decrease the plasmon intensity during the propagation to the light receiving element 8. However, the CNT 2 has such a hollow structure that it is conceived that the absorbed amount of the plasmon in the occupied volume (inside volume surrounded by the outer edge of the CNT 2, including the hollow portion) is low as compared with an ordinary material. That is to say, the amount by which the plasmon intensity is decreased during the propagation is so small that the propagation may be efficiently performed from the light emitting element 7 to the light receiving element 8.

In Example 4, the propagation of the plasmon is used as a signal and the CNT 2 may simultaneously conduct not merely light but also electric current. Thus, two signals may also be communicated by offering different information to each of light and electric current, and the information may be communicated by twice with respect to a conventional optical waveguide with the use of only light as a signal.

Examples of a method of detecting the near-field light of the CNT assembly 11 are also conceived to include a method such that a material exhibiting fast optical response is placed instead of the light receiving element 8 to detect light, which is emitted from the material by exciting this with the near-field light of the CNT assembly 11, with a photodetector, and a method of detecting scattered light of the near-field light by the material, in addition to the method as described above.

The CNT has thermal conductivity of the highest level among known materials. The utilization of this fact also allows the waveguide of Example 4 to be utilized as a waste heat path.

As described above, Example 4 allows the optical waveguide such that the propagation intensity of the plasmon as a signal is attenuated with difficulty.

In the Example, the CNT assembly 11 is formed while using the light emitting element 7 as the substrate; for example, the CNT assembly 11 may also be provided in such a manner that one end of the CNT assembly 11 contacts a position close to the light emitting element 7 on the flat plate 12 while using the flat plate 12 as the substrate, and the other end thereof is curved so as to be close to the light receiving element 8.

### Modification Example 3

FIG. 4B is a cross-sectional view showing a modification example of the optical waveguide for Example 4. FIG. 4B is such that the CNT 2 is grown in a perpendicular direction to the flat plate 12.

In this optical waveguide, the light emitting element 7 is provided at the bottom of a recess provided on the flat plate 12 (substrate). The CNT assembly 11 is provided on the light emitting element 7, and the light receiving element 8 is provided on the CNT assembly 11 so as to cover the recess of the flat plate 12. The CNT 11 is closely provided in the recess of the flat plate 12 at such a high space filling rate that light of the light emitting element 7 may reach the light receiving element 8 through the CNT 2.

The CNT assembly 11 is obtained by growing the CNT 2 while using the light receiving element 7 as the substrate. In FIG. 4B, the CNT assembly 11 is provided in the recess of the flat plate 12; in the case of providing the CNT assembly 11 in a large area, an optical waveguide may be formed by forming a trench (groove portion) on the substrate to provide the CNT assembly 11 in the trench.

### Example 5

Example 5 is an application example of the CNT assembly 11 to an optical property evaluation technique. FIG. 5 shows a perspective view of the optical property evaluation system using the CNT assembly 11 of Example 1.

In this optical property evaluation system, the CNT assembly 11 is formed on the substrate 1, and the light emitting element capable of irradiating light on the CNT 11 and an optical system 10 provided with a sensor capable of performing various optical measurements are provided on the CNT assembly. An object 9 to be measured, which is excited by light irradiation to emit light, such as biomaterials (for example, cell and DNA) may be placed on the CNT assembly 11.

When light is irradiated from the optical system 10, the object 9 emits light, and the light emission is occasionally detected with difficulty in the case of using a slight amount of the object 9 with a weak luminous efficiency, such as biomaterials.

However, the use of the CNT assembly 11 allows light of the optical system 10 to be also irradiated on the CNT assembly 11 on the periphery of the object 9. This light causes the CNT assembly 11 to emit the near-field light reinforced by the plasmon, and this emitted near-field light is also irradiated on the object 9. This near-field light has so high light intensity that the emitted light amount may be increased even in the case of using the object with a weak luminous efficiency.

The near-field light of the CNT assembly 11, which is excited by the irradiation light, has so high light intensity that the object to be measured may be analyzed even though it is of a slight amount. The CNT assembly 11 has such a high space filling rate that the interval of the CNT 2 is extremely small; therefore, the object 9 may be retained even though it is of a small size. The CNT 2 is so excellent in biocompatibility as to bring little possibility of damaging cell and DNA by reason of being of a material formed mainly out of carbon.

As described above, Example 5 allows the optical property evaluation system such as to improve luminescence intensity of the object 9.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A carbon nanotube assembly comprising a plurality of carbon nanotubes having a length of 10 μm or less in a major axis direction assembled with a space filling rate of 30% or more.

2. The carbon nanotube assembly according to claim 1, wherein any of fullerene, a metal particulate, and a semiconductor particulate is provided in the carbon nanotubes.

3. The carbon nanotube assembly according to claim 1, wherein the carbon nanotube assembly shows a reflected light spectrum depending on a reflection angle, a peak intensity of the reflected light spectrum being enhanced as the reflection angle being made larger.

4. A solar cell comprising:
a semiconductor layer; and
the carbon nanotube assembly according to claim 1 provided on the semiconductor layer,
wherein the carbon nanotube assembly shows a reflected light spectrum depending on a reflection angle in a wavelength range of 300 to 1000 nm, a peak intensity of the reflected light spectrum being enhanced as the reflection angle being made larger.

5. An optical waveguide comprising:
the carbon nanotube assembly according to claim 1, the carbon nanotube showing a reflected light spectrum depending on a reflection angle in a wavelength range of 1300 to 1600 nm, a peak intensity of the reflected light spectrum being enhanced as the reflection angle being made larger;
a light emitting element provided on one end of the carbon nanotube assembly to emit light to the end; and
a light receiving element provided on the other end of the carbon nanotube assembly to detect the light emitted from the other end.

6. A substrate with a carbon nanotube assembly comprising:
a substrate; and
the carbon nanotube assembly according to claim 1 provided on one principal surface of the substrate.

7. The substrate to claim 6, wherein the substrate is provided with a recess, and the carbon nanotube assembly is provided in the recess.
